(19) United States
(12) Patent Application Publication
(10) Pub. No.: US 2026/0236637 A1
(43) Pub. Date: Aug. 13, 2026

(54) METHOD AND APPARATUS FOR DATA COLLECTION FOR A SYSTEM IDENTIFICATION PROCESS OF A DYNAMIC SYSTEM

(71) Applicant: Sony Group Corporation, Tokyo (JP)

(72) Inventors: Thomas VAN DE WIEL, Zurich (CH); Sina MIRRAZAVI, Morges (CH)

(21) Appl. No.: 19/153,900

(22) PCT Filed: Feb. 20, 2024
(86) PCT No.: PCT/EP2024/054214

§ 371 Date: Aug. 5, 2025

(30) Foreign Application Priority Data
Feb. 20, 2023 (EP) 23157530.9

(51) Int. Cl. G06F 30/20

(52) U.S. Cl. CPC G06F 30/20

(57) ABSTRACT

Provided is an apparatus and method of data collection for a system identification process of a dynamic system. The method comprises receiving a set of motion constraints for the dynamic system. The method further comprises determining at least one motion profile for the dynamic system based on the set of motion constraints, wherein determining the motion profile comprises setting a value of the highest order derivative of motion as indicated by the set of motion constraints to a maximum, a minimum, or zero. Further, the method comprises outputting the motion profile to the dynamic system. In addition, the method comprises receiving response data indicating a response of the dynamic system to the motion profile. Further provided is a for system identification of a dynamic system, wherein the method comprises collecting data and determining a computational model of the dynamic system based on the collected data for operating the dynamic system.

### FIELD

The present disclosure relates to system identification of a dynamic system. In particular, examples of the present disclosure relate to a method of data collection for a system identification process of a dynamic system, a method for system identification of a dynamic system, an apparatus, a system, a non-transitory machine-readable medium, and a program.

### BACKGROUND

System identification is a technique for building mathematical models of dynamic system using measurements of input and output signals or data of the system. Thereby, the model of the dynamic system indicates a mathematical relationship between the input and output variables of the dynamic system. Accordingly, the system identification comprises a data collection step or process, in which the input and output data is collected, and a system modelling step or process, in which the relationship between this input and output data is captured by using a suitable computational or mathematical model. During the data collection step or process, the dynamic system is excited by providing random or pseudo-random actuation signals to the dynamic system, e.g. to the dynamic system's hardware such as actuators etc., and measuring the response of the dynamic system for different motion spectrum. However, the hardware, e.g. actuators, etc., of the dynamic system faces kinematic and dynamic limitations, so that operating the hardware, e.g. an actuator, of the dynamic system beyond this limits bear danger and/or can cause irreversible damage to the actuator, i.e. the dynamic system, itself and also to its environment. That is, conventional system identification techniques have draw-backs in terms of safety.

Hence, there may be a demand for improving system identification of a dynamic system.

### SUMMARY

This demand is met by a method of data collection for a system identification process of a dynamic system, a method for system identification of a dynamic system, an apparatus, a system, a non-transitory machine-readable medium, and a program in accordance with the independent claims. Advantageous embodiments are defined in the dependent claims.

According to a first aspect, the present disclosure provides a method of data collection for a system identification process of a dynamic system. The method comprises receiving a set of motion constraints for the dynamic system. Further, the method comprises determining at least one motion profile for the dynamic system based on the set of motion constraints, wherein determining the motion profile comprises setting a value of the highest order derivative of motion to a maximum, a minimum, or zero. In addition, the method comprises outputting the motion profile to the dynamic system. Furthermore, the method comprises receiving response data indicating a response of the dynamic system to the motion profile.

According to a second aspect, the present disclosure provides a method for system identification of a dynamic system. The method comprises collecting data according to the method of the first aspect. In addition, the method comprises determining a computational model of the dynamic system based on the collected data for operating the dynamic system.

According to a third aspect, the present disclosure provides an apparatus comprising interface circuitry configured to receive a set of motion constraints for the dynamic system. Further, the apparatus comprises processing circuitry configured to determine at least one motion profile for the dynamic system based on the set of motion constraints, wherein determining the motion profile comprises setting a value of the highest order derivative of motion as indicated by the set of motion constraints to a maximum, a minimum, or zero, and output the motion profile to the dynamic system. In addition, the interface circuitry is further configured to receive response data indicating a response of the dynamic system to the motion profile.

According to a fourth aspect, the present disclosure provides a system. The system comprises an apparatus according to the third aspect. Further, the system comprises a dynamic system, wherein a control circuitry of the dynamic system is operationally coupled to the apparatus and the control circuitry is configured to operate the dynamic system based on the motion profile output by the apparatus.

According to a fifth aspect, the present disclosure provides a non-transitory machine-readable medium having stored thereon a program having a program code for performing the method according to the first aspect and/or the second aspect, when the program may be executed on a processor or a programmable hardware.

According to a sixth aspect, the present disclosure provides a program having a program code for performing the method according to the first aspect and/or the second aspect, when the program may be executed on a processor or a programmable hardware.

### BRIEF DESCRIPTION OF THE FIGURES

Some examples of apparatuses and/or methods will be described in the following by way of example only, and with reference to the accompanying figures, in which

FIG. 1 illustrates an apparatus for data collection for a system identification process of a dynamic system;

FIG. 2 illustrates in diagrams over time an exemplary signal to be used to collect a dataset to be used in a system identification process;

FIG. 3 illustrates an exemplary system comprising an apparatus for data collection for a system identification process of a dynamic system and a dynamic system;

FIG. 4 illustrates in a flow chart an exemplary method of data collection for a system identification process of a dynamic system; and

FIG. 5 illustrates in a flow chart an exemplary method for system identification of a dynamic system.

### DETAILED DESCRIPTION

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, i.e., only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

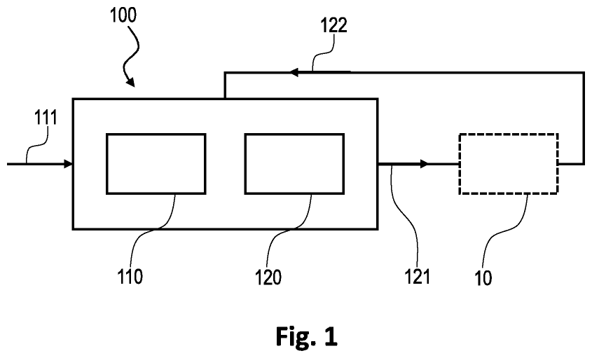

FIG. 1 illustrates an exemplary apparatus 100 for data collection for a system identification process of a dynamic system 10. The dynamic system 10 may be any kind of system that is not static but evolves its state with respect to time. It may be any controllable device, system, actuator or the like that that can be controlled for motion and/or corresponding tasks, e.g. in industrial applications. For example, the dynamic system 10 may be a single actuator, an industrial robot, or the like. In at least some examples, the dynamic system 10 may be any robot with n degrees of freedom, where n is an integer equal to or greater than 1. Thereby, the dynamic system 10 may be applied to an industrial environment for e.g., production, logistics, or the like. The dynamic system 10, and/or an actuator thereof, may be configurable, manipulable and/or controllable to provide or effect movement, a pose, etc., For example, the dynamic system 10 may comprise one or more of a link, joint, actuator, manipulator, etc., which may be controlled individually or simultaneously, e.g. via at least one actuator. Further, the dynamic system 10 may be configured to be controllable, e.g. via a suitable control circuitry, such as a controller, e.g. a low-level controller, or the like. For example, the control circuitry may be configured to control the dynamic system 10 on at least one of a position level, a velocity level, an acceleration level, and a jerk level of the dynamic system 10. Further, the control circuitry may be configured to track signals, e.g. input signals or data, output signals or data, etc. However, it is to be noted that the dynamic system 10 is not limited to the foregoing examples. Generally, the apparatus 100 is configured for data collection for a system identification process of the dynamic system 10.

As used herein, the system identification process may be understood as a technique, methodology or the like for determining a mathematical or computational model of a dynamic system, such as the dynamic system 10, using measurements of input and output signals of the system. The system identification process may comprise a data collection step or process, in which input signals or data and output signals or data of the dynamic system 10 are collected, and a system modelling step or process, in which the relationship between this input and output signals or data is captured by using a suitable computational or mathematical model, such as a parametric or non-parametric model, etc. Thereby, the computational (or mathematical) model may be understood as a mathematical relationship between input and output parameters, variables, etc. of the dynamic system 10. Such a model may be described by, for example, differential or difference equations, transfer functions, state-space equations, pole-zero-gain models, or the like. For example, the model may be represented in continuous-time form or discrete-time form, wherein other representations of the model are also conceivable. The input and output signals or data may be provided and measured in time domain or frequency domain. The system identification process aims on determining the respective model, e.g. its parameters, variables, or the like, for the dynamic system 10, wherein the determined, e.g. identified, model may be used to improve performance of the dynamic system 10, e.g. in terms of cycle time, energy efficiency, etc., by applying the determined model to control circuitry of the dynamic system 10 for a model-based control and/or operation thereof. Accordingly, in at least some examples, the apparatus 100 may be configured to determine the respective computational model of the dynamic system 10 based on the collected data for operating the dynamic system 10. In such case, the apparatus 100 may also be extended and/or referred to as a system identification apparatus.

The apparatus 100 comprises at least interface circuitry 110 and processing circuitry 120. The processing circuitry 120 is operatively connected to the interface circuitry 110. The apparatus 100 is operatively connected to the dynamic system 10, which in FIG. 1 is illustrated by dashed lines, as the apparatus 100 may be applied to any suitable dynamic system.

The interface circuitry 110 is configured to receive a set of motion constraints 111 for the dynamic system 10. For example, the set of motion constraints 111 may be a dataset. The set of motion constraints may comprise one or more kinematic constraints including a minimum joint position, a maximum joint position, a maximum velocity, a maximum acceleration, and a maximum jerk. Thereby, for the apparatus 100, it may be assumed that the velocity, acceleration constraints are symmetric, i.e. the minimum is equal to the negative sign of the maximum. Further, the set of motion constraints 111 may comprise one or more of a state constraint associated with a state of the dynamic system 10, which may include kinematic constraints such as minimum and/or maximum values of joint position, velocity, acceleration, jerk, etc., an environment constraint associated with the environment of the dynamic system 10, or the like. Further, the constraints may be defined or specified at the level of position, velocity, acceleration and/or jerk, wherein further derivatives of motion are also conceivable. Merely by way of example, constraints associated with the dynamic system 10 may include one or more of or may be referred to as an upper state constraint c̅ₓ, a lower state constraint cₓ, an upper input constraint c̅ᵤ, a lower input constraint cᵤ, an upper environment constraint c̅ₑ, and a lower environment constraint cₑ, wherein these are merely examples and there may also be different or more specific constraints, such as the above-mentioned minimum and/or maximum values of joint position, velocity, acceleration, jerk, etc. constraints. A corresponding reference signal to be input into the dynamic system 10 within the system identification process and/or the data collection step or process may be denoted or referred to as u. It is noted that the state of the dynamic system 10, i.e. its position and its higher order derivatives, remain within its constraints if the reference position signal and its derivatives remain within these same state constraints. The same applies to the environment constraints. Accordingly, the task of satisfying the above constraints can be simplified to configure, e.g. construct, the reference signal u in a manner that the reference position and all of its derivatives satisfy the most restrictive one of these constraints on the corresponding state of the dynamic system 10. By way of example, the highest value of the lower constraints may be lower than the lowest value of the upper constraints, which may be expressed by the following mathematical ex-pressions:

$$max ( \underline{{c}_{x}} , \underline{{c}_{u}} , \underline{{c}_{e}} ) < u ( t ) < min ( \overline{{c}_{x}} , \overline{{c}_{u}} , \overline{{c}_{e}} ) and$$

$$min ( \underline{{c}_{\dot{x}}} , \underline{{c}_{\dot{u}}} , \underline{{c}_{\dot{e}}} ) < \dot{u} ( t ) < min ( \overline{{c}_{\dot{x}}} , \overline{{c}_{\dot{u}}} , \overline{{c}_{\dot{e}}} ) ,$$

wherein this may be set forth for the further higher order derivatives of u(t), denoting the reference signal. The apparatus 100 may be configured to determine the most restrictive constraint of the set of constraints 111 which is to be complied with.

The processing circuitry 120 is configured to determine at least one motion profile 121 for the dynamic system 10 based on the set of motion constraints 111, wherein determining the motion profile 121 comprises setting a value of a highest order derivative of motion as indicated by the set of motion constraints to a maximum, a minimum, or zero. For example, the above-mentioned reference signal u may be part of, may be included in, or may form the at least one motion profile 121. Thereby, the processing circuitry 120 may be configured to set the value of the highest order derivative of motion value to satisfy the above-mentioned most restrictive constraint of the set of constraints 111. For example, setting the value of the highest order derivative of motion comprises determining active and/or inactive kinematic constraints indicated by the set of constraints 111. Further, as mentioned above, the dynamic system 10 may be configured, e.g. by comprising respective control circuitry, to be controlled on a jerk level, wherein jerk may be denoted by j and expressed in m/s³ or rad/s³. It is noted that operating the dynamic system 10 at its jerk limit(s) covers a wide band or range of velocity and acceleration of the dynamic system 10, so that a rich data set for the system identification can be collected. In such case, the processing circuitry 120 may be configured to set the jerk j to either maximum, minimum, or zero, e.g. as indicated by the set of motion constraints 111. It is noted that the foregoing principle may also be applied to other higher or highest order derivatives as well. Further, the processing circuitry 120 is configured to output the motion profile 121 to the dynamic system 10. The motion profile 121 may form the input signal(s) or data of the dynamic system 10 to be collected in or during the above-mentioned data collection step or process of the system identification process. The motion profile 121 may be configured to excite the dynamic system 10 accordingly, so that the motion profile 121, which may comprise the reference signal u may also be referred to as stimulation signal, actuation signal, or the like.

In addition, the interface circuitry 110 is further configured to receive response data 122 indicating a response of the dynamic system 10 to the motion profile 121. The response data 122 may indicate a tracking of motion of the dynamic system 10 caused by operating the dynamic system 10 based on the motion profile 121. The response data 122 may form the output signal(s) or data of the dynamic system 10 to be collected in or during the above-mentioned data collection step or process of the system identification process. The response data 122 may be provided by the apparatus 100, a control circuitry of the dynamic system 10 or a combination thereof.

The apparatus, method and system described herein allows for generating an actuation signal, i.e. the motion profile 121, that complies with all constraints associated with the dynamic system 10, such that the data, e.g. data set, for system identification can be safely collected by sending the generated actuation signal, i.e. the motion profile 121 to the dynamic system 10. This improves safety of the system identification process for and/or the operation of the dynamic system 10 while ensuring richness of the collected data.

Based on the above, the apparatus 100 may be modified in many ways.

For example, for determining the motion profile 121, the processing circuitry 120 may be configured to construct the above-mentioned reference signal u such that the entire band or range of allowed position of the dynamic system 10 can be covered, wherein the same may be made for velocity, acceleration, and one or more higher order derivatives under consideration. For instance, the processing circuitry 120 may be configured to construct the above-mentioned reference signal u such that a discretization grid with N steps is defined, wherein the processing circuitry 120 may be configured to allow that each grid point is reached or visited from each other grid point, i.e. every possible start point or position may be match with every possible end point or position. Thereby, for a discretization grid of N steps, the total number of start-end pairs may thus be of size N².

In addition, the processing circuitry 120 may be configured to generate a trajectory, e.g. a position trajectory, from a start position to an end position within the motion profile 121. Further, the processing circuitry 120 may be configured to set, for determining the motion profile 121, a start state and an end state of the dynamic system 10 within the motion profile 121 to be stationary, i.e. the velocity and acceleration are zero. In addition, for determining the motion profile 121, the processing circuitry 120 may be configured to set a time duration for motion from the start to the end position. Thereby, the time duration allowed for executing the motion from the start position to the end position determines the velocity and acceleration values that will be reached during the motion and can be used as a tuning parameter to obtain a high coverage of the velocity acceleration band or range. In at least some examples, a sequence of multiple motion profiles may be determined, which may be summarized, combined, etc. to the motion profile 121, to cover an allowed position space of the dynamic system, wherein each motion profile of the sequence comprises a segment of a trajectory from a start position to an end position, and the start position of the respective subsequent segment of the trajectory is the end position of the preceding segment of the trajectory.

Further, as described above, the processing circuitry 120 is configured to set the value of the highest order derivative, e.g. the jerk j, to either minimum or maximum or zero. In at least some examples, the processing circuitry 120 may be configured to set the value of the highest order derivative of motion value to one of the maximum and minimum for a first duration of motion and to the other one of the maximum and minimum, or zero (e.g. if the dynamic system 10 is moving with zero acceleration at its velocity limit, etc.) for a second duration of motion, if the set of motion constraints 111 indicates inactive velocity and acceleration constraints. For example, in case of inactive velocity and acceleration constraints, the motion profile 121 may be determined such that the end state may be reached by using the extreme jerk value with sign equal to the sign of p_{end}−pₛₜₐᵣₜ in the first half of the duration of the motion and with a jerk of opposite sign for the second half of the duration of the motion. This ensures zero velocity and acceleration at the target or end state. Further, by way of example, in case the velocity limit(s) are reached, the processing circuitry 120 may be configured to set the jerk such that the limit is reached with zero acceleration. The acceleration phase may be followed by a constant velocity phase that lasts 0≤t [s]. This may be followed by a deceleration phase that is symmetric to the acceleration phase, bringing velocity and acceleration back to zero at the time the target is reached. In case the acceleration or higher order limit(s) are reached, the processing circuitry 120 may be configured to extend the foregoing procedure.

In addition, the functionalities of the processing circuitry 120 may be implemented, for example, by the open-source package Ruckig, which is accessible via the Internet on e.g. Github (see URL: https://github.com/pantor/ruckig). It should be noted, however, that this merely an exemplary implementation and other methods to construct feasible, highly dynamic motion profiles between the earlier defined start-end pairs are also conceivable.

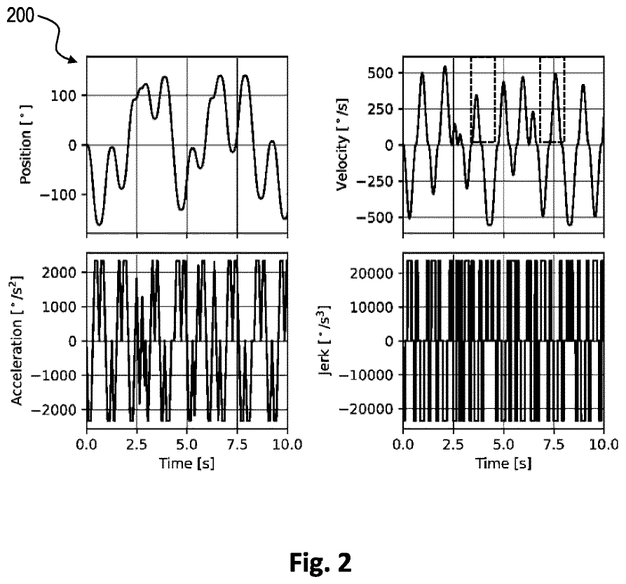

FIG. 2 illustrates an exemplary signal 200, which may be the above-mentioned reference signal u, which may be part of or may form the motion profile 121. As described above, the signal 200, e.g. reference signal u, can be used to collect a dataset to be used in the above-described system identification process.

FIG. 2 illustrates four diagrams, one of which showing the reference signal u for the dynamic system 10 on position level in [°] (see diagram top left), velocity level in [°/s] (see diagram top right), acceleration level in [°/s²] (see diagram bottom left) and jerk level in [°/s³] (see diagram bottom right) over time in [s]. According to FIG. 2, for example, the velocity constraints, as e.g. indicated by the set of constraints 111, are active at around 2.5 and 6 seconds. Also, in the exemplary time range shown, the acceleration and jerk constraints are reached numerous times.

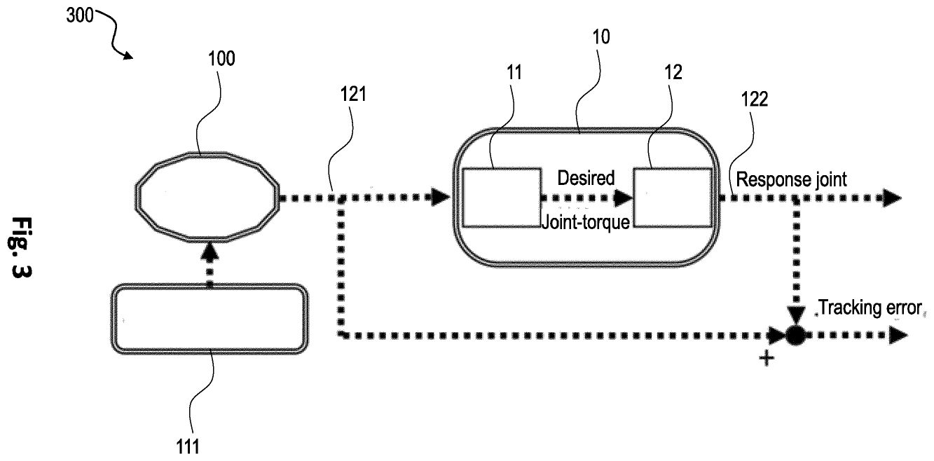

FIG. 3 illustrates a system 300 comprising the above-described apparatus 100 and the dynamic system 10. The system may be used for the above-described system identification process, including the data collection step or process and the system modelling step or process.

The dynamic system 10 comprises control circuitry 11, which is coupled or operationally connected to the apparatus 100. The control circuitry 11 may be configured to operate the dynamic system 10 based on the above-described motion profile 121 output by the apparatus 100. Further, the dynamic system 10 comprises at least one actuator 12 coupled to the control circuitry 11 to be controlled for operation. The control circuitry 11 may be configured to control the dynamic system 10 on at least one of a position level, a velocity level, an acceleration level, and a jerk level of the dynamic system 10. In at least some examples, the control circuitry 11 may also be referred to as a low-level controller, which may be integrated in the dynamic system 10. The control circuitry 11 may be configured to track the above-described reference signal u.

Further, as mentioned above, the dynamic system 10 may comprise one or more of a link, joint, actuator, manipulator, etc., which may be controlled individually or simultaneously, e.g. via the at least one actuator 12. At least one of the apparatus 100 and the control circuitry 11 may be configured to provide the above-described response data 122 indicating the response of the dynamic system 10 to the motion profile 121.

The apparatus 100 may be configured to determine the computational model comprises comparing the motion profile 121 and the response data 122 indicating the response of the dynamic system 10 to the motion profile 121.

As described above, the apparatus 100 may be configured to determine, e.g. generate the at least one motion profile 121, which may include the reference signal u and/or a set of reference trajectories. Then, the motion profile 121 is provided, e.g. sent, to the dynamic system 10. Thereby, the identification may be performed in synchrony or asynchrony with an internal clock of the dynamic system, e.g. of control circuitry 11. That is, in the former case, the motion profile 121 may be provided with a single reference to the dynamic system 10 to collect its response to this input. In the latter case, the motion profile 121 may be provided with a trajectory at once to the dynamic system 10, which may be controlled to follow the trajectory once the entire trajectory is received.

The apparatus 100 and/or the system 300 as described herein enables identifying the dynamics of the dynamic system 10, e.g. by determining, e.g. identifying, the above-described computational model on the position level or any of its derivatives. The identified computational model can be used to improve the performance of the dynamic system 10 in terms of e.g. cycle time, energy efficiency, etc.

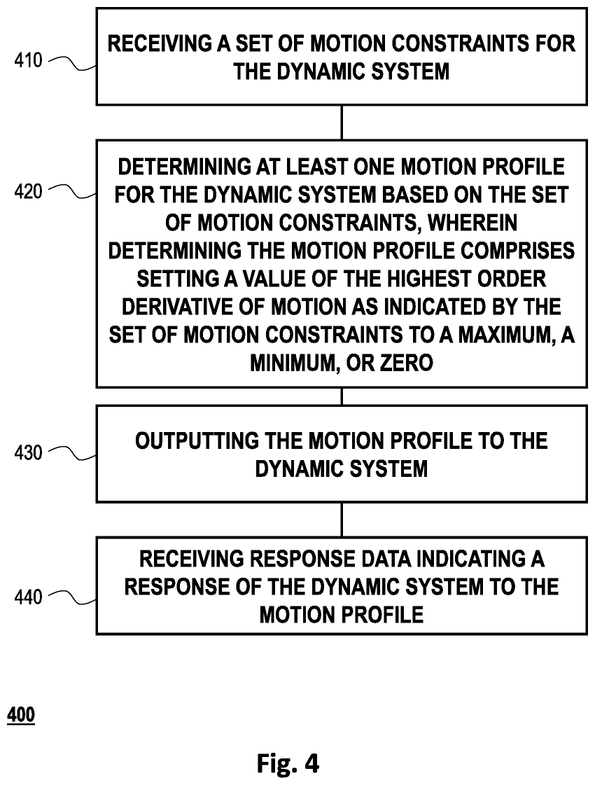

For further highlighting the data collection for a system identification process of a dynamic system described above, FIG. 4 illustrates in a flowchart a method 400 of data collection for a system identification process of a dynamic system. For example, the method 400 may be carried out by the above apparatus 100 and/or system 300.

The method comprises receiving 410 a set of motion constraints for the dynamic system. Further, the method comprises determining 420 at least one motion profile for the dynamic system based on the set of motion constraints, wherein determining the motion profile comprises setting a value of the highest order derivative of motion as indicated by the set of motion constraints to a maximum, a minimum, or zero. In addition, the method comprises outputting 430 the motion profile to the dynamic system. Further, the method comprises receiving 440 response data indicating a response of the dynamic system to the motion profile.

The method 400 may allow improving safety of the system identification process for and/or the operation of the dynamic system 10 while ensuring richness of the collected data.

More details and aspects of the method 400 are explained in connection with the proposed technique or one or more examples described above (e.g., FIG. 1 to FIG. 3). The method 400 may comprise one or more additional optional features corresponding to one or more aspects of the proposed technique or one or more examples described above.

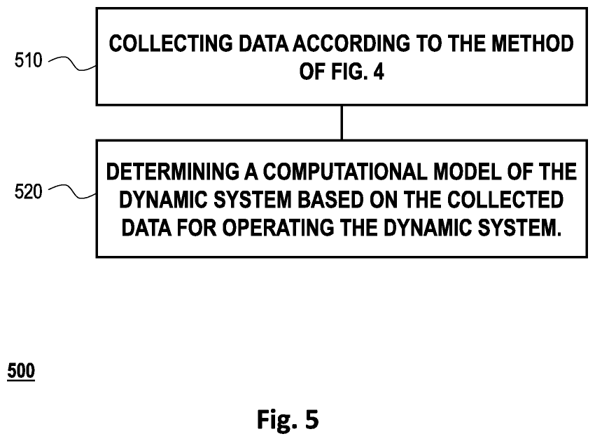

For further highlighting the system identification process for a dynamic system described above, FIG. 5 illustrates in a flowchart a method 500 for system identification of a dynamic system. For example, the method 500 may be carried out by the above apparatus 100 and/or system 300.

The method 500 comprises collecting 510 data according to the above method 400. Further the method comprises determining 520 a computational model of the dynamic system based on the collected data for operating the dynamic system.

The following examples pertain to further embodiments:

(1) A method of data collection for a system identification process of a dynamic system, the method comprising:
receiving a set of motion constraints for the dynamic system;
determining at least one motion profile for the dynamic system based on the set of motion constraints, wherein determining the motion profile comprises setting a value of the highest order derivative of motion as indicated by the set of motion constraints to a maximum, a minimum, or zero;
outputting the motion profile to the dynamic system; and
receiving response data indicating a response of the dynamic system to the motion profile.

(2) The method of (1), wherein determining the motion profile comprises setting a start state and an end state of the dynamic system within the motion profile to be stationary.

(3) The method of (1) or (2), wherein determining the motion profile comprises generating a trajectory from a start position to an end position within the motion profile.

(4) The method of (3), wherein determining the motion profile comprises setting a time duration for motion from the start position to the end position.

(5) The method of any one of (1) to (4), wherein determining the motion profile comprises determining the most restrictive constraint of the set of constraints and setting the value of the highest order derivative of motion value to satisfy the most restrictive constraint.

(6) The method of any one of (1) to (5), wherein a sequence of multiple motion profiles is determined to cover an allowed position space of the dynamic system, each motion profile of the sequence comprises a segment of a trajectory from a start position to an end position, and the start position of the respective subsequent segment of the trajectory is the end position of the preceding segment of the trajectory.

(7) The method of any one of (1) to (6), wherein setting the value of the highest order derivative of motion comprises determining active and/or inactive kinematic constraints indicated by the set of constraints.

(8) The method of (7), wherein the value of the highest order derivative of motion value is set to one of the maximum and minimum for a first duration of motion and to the other one of the maximum and minimum for a second duration of motion, if the set of motion constraints indicates inactive velocity and acceleration constraints.

(9) The method of (8), wherein the value of the highest order derivative of motion value for the first duration of motion is set to have a sign equal to a sign of a difference between an end position and a start position within the motion profile and to have a sign opposite to the to the difference between the end position and the start position for the second duration of motion.

(10) The method of any one of (1) to (9), wherein the set of motion constraints comprises one or more kinematic constraints including a minimum joint position, a maximum joint position, a maximum velocity, a maximum acceleration, and a maximum jerk.

(11) The method of any one of (1) to (10), wherein the highest order derivative is jerk of the dynamic system.

(12) The method of any one of (1) to (11), wherein the response data indicates a tracking of motion of the dynamic system caused by operating the dynamic system based on the motion profile.

(13) A method for system identification of a dynamic system, the method comprising: collecting data according to the method of any one of (1) to (12); and determining a computational model of the dynamic system based on the collected data for operating the dynamic system.

(14) The method of (13), wherein determining the computational model comprises parametrizing the computational model based on the collected data.

(15) The method of (13) or (14), wherein determining the computational model comprises comparing the motion profile and the response data indicating the response of the dynamic system to the motion profile.

(16) An apparatus, comprising:
interface circuitry configured to receive a set of motion constraints for the dynamic system; and
processing circuitry configured to:
determine at least one motion profile for the dynamic system based on the set of motion constraints, wherein determining the motion profile comprises setting a value of a highest order derivative of motion as indicated by the set of motion constraints to a maximum, a minimum, or zero; and
output the motion profile to the dynamic system;
wherein the interface circuitry is further configured to receive response data indicating a response of the dynamic system to the motion profile.

(17) The apparatus of (16), wherein the apparatus is configured to identify a computational model of the dynamic system based on the collected data.

(18) A system, comprising:
an apparatus according to (16) or (17); and
a dynamic system, wherein a control circuitry of the dynamic system is operationally coupled to the apparatus and the control circuitry is configured to operate the dynamic system based on the motion profile output by the apparatus.

(19). The system of (18), wherein the dynamic system comprises at least one actuator operationally coupled to the control circuitry.

(20) The system of (18) or (19), wherein at least one of the apparatus and the control circuitry is configured to provide the response data indicating the response of the dynamic system to the motion profile.

(21) The system of any one of (18) to (20), wherein the control circuitry is configured to control the dynamic system on at least one of a position level, a velocity level, an acceleration level, and a jerk level of the dynamic system.

(22) A non-transitory machine-readable medium having stored thereon a program having a program code for performing the method according to any one of (1) to (12) and/or the method according to any one of (13) to (15), when the program is executed on a processor or a programmable hardware.

(23) A program having a program code for performing the method according to any one of (1) to (12) and/or the method according to any one of (13) to (15), when the program is executed on a processor or a programmable hardware.

The aspects and features described in relation to a particular one of the previous examples may also be combined with one or more of the further examples to replace an identical or similar feature of that further example or to additionally introduce the features into the further example.

Examples may further be or relate to a (computer) program including a program code to execute one or more of the above methods when the program is executed on a computer, processor or other programmable hardware component. Thus, steps, operations or processes of different ones of the methods described above may also be executed by programmed computers, processors or other programmable hardware components. Examples may also cover program storage devices, such as digital data storage media, which are machine-, processor- or computer-readable and encode and/or contain machine-executable, processor-executable or computer-executable programs and instructions. Program storage devices may include or be digital storage devices, magnetic storage media such as magnetic disks and magnetic tapes, hard disk drives, or optically readable digital data storage media, for example. Other examples may also include computers, processors, control units, (field) programmable logic arrays ((F)PLAs), (F)PGA), graphics processor units (GPU), ASICs, integrated circuits (ICs) or system-on-a-chip (SoCs) systems programmed to execute the steps of the methods described above.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

1. A method of data collection for a system identification process of a dynamic system, the method comprising:
receiving a set of motion constraints for the dynamic system;
determining at least one motion profile for the dynamic system based on the set of motion constraints, wherein determining the motion profile comprises setting a value of the highest order derivative of motion as indicated by the set of motion constraints to a maximum, a minimum, or zero;
outputting the motion profile to the dynamic system; and
receiving response data indicating a response of the dynamic system to the motion profile.

2. The method of claim 1, wherein determining the motion profile comprises setting a start state and an end state of the dynamic system within the motion profile to be stationary.

3. The method of claim 1, wherein determining the motion profile comprises generating a trajectory from a start position to an end position within the motion profile.

4. The method of claim 3, wherein determining the motion profile comprises setting a time duration for motion from the start position to the end position.

5. The method of claim 1, wherein determining the motion profile comprises determining the most restrictive constraint of the set of constraints and setting the value of the highest order derivative of motion value to satisfy the most restrictive constraint.

6. The method of claim 1, wherein a sequence of multiple motion profiles is determined to cover an allowed position space of the dynamic system, each motion profile of the sequence comprises a segment of a trajectory from a start position to an end position, and the start position of the respective subsequent segment of the trajectory is the end position of the preceding segment of the trajectory.

7. The method of claim 1, wherein setting the value of the highest order derivative of motion comprises determining active and/or inactive kinematic constraints indicated by the set of constraints.

8. The method of claim 7, wherein the value of the highest order derivative of motion value is set to one of the maximum and minimum for a first duration of motion and to the other one of the maximum and minimum for a second duration of motion, if the set of motion constraints indicates inactive velocity and acceleration constraints.

9. The method of claim 8, wherein the value of the highest order derivative of motion value for the first duration of motion is set to have a sign equal to a sign of a difference between an end position and a start position within the motion profile and to have a sign opposite to the to the difference between the end position and the start position for the second duration of motion.

10. The method of claim 1, wherein the set of motion constraints comprises one or more kinematic constraints including a minimum joint position, a maximum joint position, a maximum velocity, a maximum acceleration, and a maximum jerk.

11. The method of claim 1, wherein the highest order derivative is jerk of the dynamic system.

12. The method of claim 1, wherein the response data indicates a tracking of motion of the dynamic system caused by operating the dynamic system based on the motion profile.

13. A method for system identification of a dynamic system, the method comprising:
collecting data according to the method of any claim 1; and
determining a computational model of the dynamic system based on the collected data for operating the dynamic system.

14. The method of claim 13, wherein determining the computational model comprises comparing the motion profile and the response data indicating the response of the dynamic system to the motion profile.

15. An apparatus, comprising:
interface circuitry configured to receive a set of motion constraints for the dynamic system; and
processing circuitry configured to:
determine at least one motion profile for the dynamic system based on the set of motion constraints, wherein determining the motion profile comprises setting a value of the highest order derivative of motion as indicated by the set of motion constraints to a maximum, a minimum, or zero; and
output the motion profile to the dynamic system;
wherein the interface circuitry is further configured to receive response data indicating a response of the dynamic system to the motion profile.

16. The apparatus of claim 15, wherein the apparatus is configured to identify a computational model of the dynamic system based on the collected data.

17. A system, comprising:
an apparatus according to claim 15; and
a dynamic system, wherein a control circuitry of the dynamic system is operationally coupled to the apparatus and the control circuitry is configured to operate the dynamic system based on the motion profile output by the apparatus.

18. The system of claim 17, wherein at least one of the apparatus and the control circuitry is configured to provide the response data indicating the response of the dynamic system to the motion profile.

19. The system of claim 17, wherein the control circuitry is configured to control the dynamic system on at least one of a position level, a velocity level, an acceleration level, and a jerk level of the dynamic system.

20. A non-transitory machine-readable medium having stored thereon a program having a program code for performing the method according to claim 1 when the program is executed on a processor or a programmable hardware.
